(19) United States
(12) Patent Application Publication
(10) Pub. No.: US 2025/0218915 A1
(43) Pub. Date: Jul. 3, 2025

(54) PEDESTAL STRUCTURE FOR PASSIVE CIRCUIT COMPONENT STRUCTURE

(71) Applicant: Intel Corporation, Santa Clara, CA (US)

(72) Inventors: Tolga Acikalin, San Jose, CA (US); Soham Agarwal, Chandler, AZ (US); Benjamin T. Duong, Phoenix, AZ (US); Jeremy D. Ecton, Gilbert, AZ (US); Kari E. Hernandez, Phoenix, AZ (US); Brandon Christian Marin, Gilbert, AZ (US); Pratyush Mishra, Tempe, AZ (US); Pratyasha Mohapatra, Hillsboro, OR (US); Srinivas V. Pietambaram, Chandler, AZ (US); Marcel M. Said, Beaverton, OR (US); Gang Duan, Chandler, AZ (US); Hiroki Tanaka, Gilbert, AZ (US); Robert A. May, Chandler, AZ (US); Bai Nie, Chandler, AZ (US); Sanjay Tharmarajah, Queen Creek, AZ (US); Bohan Shan, Chandler, AZ (US)

(73) Assignee: Intel Corporation, Santa Clara, CA (US)

(21) Appl. No.: 18/401,234

(22) Filed: Dec. 29, 2023

(51) Int. Cl. H01L 23/498; H01L 23/00; H01L 23/31; H01L 23/48; H01L 25/065

(52) U.S. Cl. CPC H01L 23/49838; H01L 23/3121; H01L 23/481; H01L 23/49822; H01L 24/16; H01L 25/0655; H01L 2224/16225; H01L 2924/1431

(57) ABSTRACT

An apparatus comprising a package substrate comprising a core layer; a pedestal embedded in the core layer; and a structure comprising a passive circuit component, wherein the structure is above the pedestal and is embedded in the core layer.

### BACKGROUND

A package substrate may be used in an electronic device to provide electrical and mechanical support to integrated circuit components coupled thereto. A package substrate may host a network of conductive traces that connect various components on the surface of the package substrate. The package substrate may also feature conductive pathways (e.g., vias) that traverse the layers of the substrate, enabling connections between different layers of the package substrate. A package substrate may provide electrical connection between one or more integrated circuit components and various circuits of a printed circuit board upon which the package substrate is mounted.

### BRIEF DESCRIPTION OF THE DRAWINGS

FIG. 1 illustrates a package with an embedded passive component structure and a pedestal, in accordance with any of the embodiments disclosed herein.

FIG. 2 illustrates a package with an embedded passive component structure and a pedestal with vias, in accordance with any of the embodiments disclosed herein.

FIG. 3 illustrates a package with an embedded passive component structure and a pedestal with conductive material on its outer edge, in accordance with any of the embodiments disclosed herein.

FIG. 4 illustrates example stages of a first method of manufacture of a package substrate with an embedded passive component structure and a pedestal, in accordance with any of the embodiments disclosed herein.

FIG. 5 illustrates example stages of a second method of manufacture of a package substrate with an embedded passive component structure and a pedestal, in accordance with any of the embodiments disclosed herein.

FIG. 6 illustrates example stages of a third method of manufacture of a package substrate with an embedded passive component structure and a pedestal, in accordance with any of the embodiments disclosed herein.

FIG. 7 provides a schematic illustration of a cross-sectional view of an example integrated circuit device, in accordance with any of the embodiments disclosed herein.

FIG. 8 is a top view of a wafer and dies that may be included in a microelectronic assembly, in accordance with any of the embodiments disclosed herein.

FIG. 9 is a cross-sectional side view of an integrated circuit device that may be included in a microelectronic assembly, in accordance with any of the embodiments disclosed herein.

FIGS. 10A-10D are perspective views of example planar, FinFET, gate-all-around, and stacked gate-all-around transistors.

FIG. 11 is a cross-sectional side view of an integrated circuit device assembly that may include a microelectronic assembly, in accordance with any of the embodiments disclosed herein.

FIG. 12 is a block diagram of an example electrical device that may include a microelectronic assembly, in accordance with any of the embodiments disclosed herein.

### DETAILED DESCRIPTION

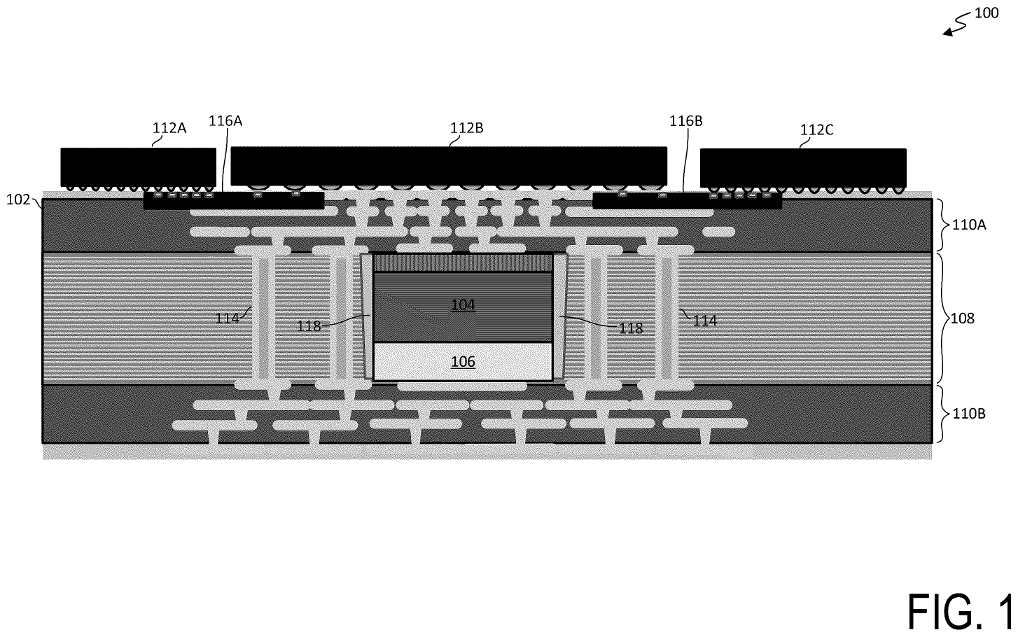

FIG. 1 illustrates a package 100 comprising a package substrate 102 with an embedded passive component structure 104 and a pedestal 106, in accordance with any of the embodiments disclosed herein. The package substrate 102 may comprise a core layer 108, a first outer layer 110A on the core layer 108, and a second outer layer 110B under the core layer 108.

Package substrate 102 functionality may be supplemented by embedding a passive component structure 104 within the core layer 108. For example, one proposal for enabling a fully integrated voltage regulation (FIVR) circuit within the package substrate 102 is to incorporate passive components into the substrate core layer 108. For example, one solution involves picking and placing a discrete capacitor (e.g., a deep trench capacitor (DTC)) into a cavity of the core layer followed by an encapsulation process (e.g., by a mold or other dielectric) that places the encapsulation material around the component. In various instances (e.g., when the discrete capacitor is fabricated using silicon technology), the thickness of the capacitor may be limited (e.g., in the range of 100 to 1000 microns) due to various constraints (e.g., in the silicon wafer thickness and process limitations). This thickness limitation may be an issue for substrate core layers that are thicker than the passive component structure (e.g., the thickness of a core layer could range from 100 microns to 3 millimeters), since the passive component structure may be prone to shifting or rotation within the cavity of the core layer during and after encapsulation. Thus, various issues may arise such as misalignment, rotational shift, tilting, or encapsulation thickness variations.

In various embodiments of the present disclosure, the thickness mismatch between the core layer 108 and a passive component structure 104 may be compensated by a pedestal 106 placed underneath the passive component structure 104. In some embodiments, the thickness of the pedestal 106 may be configured such that the combined thickness of the pedestal 106 and the passive component structure 104 is substantially equal to thickness of the core layer 108. The pedestal 106 may comprise a rigid material (e.g., glass, ceramic, silicon, a metal, etc.) to provide structural support to the passive component structure 104.

Various embodiments may provide one or more advantages, such as elimination of the need for encapsulation material underneath the passive component structure, improved alignment of the passive component structure, better attachment of the passive component structure to the package, and improved embedding yield.

One side of the package substrate 102 may interface with one or more chips 112 (e.g., 112A, 112B, and 112C). For example, the top side of the package substrate 102 may include conductive contacts (e.g., solder pads) that couple to conductive contacts of the chips 112 (e.g., via a solder connection). Another side of the package substrate 102 that is opposite to the first side may interface with a circuit board, other chips, and/or passive component structures. For example, the bottom side of the package substrate 102 may include a plurality of conductive contacts (e.g., solder pads). Solder balls may be formed on the conductive contacts and used to couple the conductive contacts of the package substrate 102 to corresponding conductive contacts of the circuit board. A conductive contact may comprise any suitable conductive material (e.g., copper) arranged in any suitable shape.

The package substrate 102 may include a core layer 108, a first outer layer 110A, and a second outer layer 110B. At least a portion of the outer layers 110 may comprise alternating conductive layers and insulating layers, where a conductive layer may have any number of different (e.g., electrically isolated) interconnects on the same plane of the package substrate 102. The package substrate may also include a plurality of plated through hole (PTH) vias 114 that extend from a top side of the core layer 108 to the bottom side of the core layer 108. A PTH via 114 may comprise a hole that goes through the package substrate 102 and has its walls plated with a conductive material (e.g., copper). A PTH via may provide a conductive path from an interconnect of one conductive layer of the package substrate 102 to an interconnect of another conductive layer.

The core layer 108 may comprise any suitable dielectric material that may provide structural support. For example, the core layer 108 may comprise one or more of glass, a resin material (e.g., bismaleimide triazine), a fiberglass weave, a ceramic material, an epoxy-based laminate material reinforced with glass fibers, silicon, a laminate (e.g., a polyimide), a ceramic material, an organic polymer, and one or more fillers (e.g., silicon dioxide, glass beads, silica particle fillers).

In some embodiments, an outer layer 110 may comprise a laminate comprising alternating layers of patterned metal (e.g., copper) forming signal or power/ground plane layers and one or more dielectric materials to electrically isolate the patterned metal. The outer layers 110 may comprise any suitable dielectric materials including one or more of an organic resin (e.g., Ajinomoto Build-up Film), silicon oxide beads, inorganic dielectrics (e.g., silicon dioxide, silicon nitride, etc.), or suitable filler materials (e.g., silica particle fillers). In some embodiments, the outer layer 110 (or at least some of the layers of an outer layer) do not have fibers.

The package substrate may be coupled to any number of dies 112 (e.g., 112A-C), e.g., via a flip chip technique, wire bonding, and/or other suitable couplings. The dies 112 may include any suitable logic. For example, a die 112 may comprise a central processing unit, another processor, a transceiver, or other suitable logic. In some embodiments, one or more bridges 116 (e.g., 116A, 116B) may be embedded within the outer layer 110A. A bridge 116 may comprise a die with conductive material (e.g., a plurality of metal layers) to provide connections between pads of two or more chips 112. In one embodiment, a bridge 116 is an embedded multi-die interconnect bridge (EMIB). In various embodiments, an EMIB is a small silicon chip embedded in the package substrate under the edges of the chips the EMIB couples together. In some embodiments, an EMIB may couple pads of a chip to pads of another chip without using TSVs. In various embodiments, a plurality of EMIBs may be embedded in a single package substrate 102 with each EMIB coupling two chips together.

The passive component structure 104 may comprise any suitable passive circuit component, such as a capacitor, inductor, or resistor. In some embodiments, a passive component structure 104 may comprise multiple components of the same type or of varying types.

In a particular embodiment, the passive component structure comprises a deep trench capacitor. In some embodiments, the electrodes of the deep trench capacitor may comprise two electrical conductors (e.g., doped silicon) separated by an insulator.

In some instances, a deep trench capacitor may be formed by etching thin, deep trenches into a semiconductor material (e.g., silicon) that is doped (e.g., to form a buried plate) and then lining the trenches with a dielectric material and filling them with a conductive material (e.g., an inner electrode). A deep trench capacitor may provide a high capacitance per unit area relative to other structures, especially when coupled in parallel. In the embodiment depicted, the alternating vertical lines at the top of the passive component structure 104 are meant to depict the trenches of a deep trench capacitor.

The passive component structure 104 may be placed on top of a pedestal 106. In various embodiments, the pedestal 106 may comprise a rigid material to provide structural support to the passive component structure 104, such as one or more of glass, ceramic, silicon, a metal (e.g., copper coin). In some embodiments, the pedestal 106 may comprise a die.

The passive component structure 104 may be attached to the pedestal 106 in any suitable manner, such as a die bond film, an adhesion layer, bump bonding, hybrid bonding. In some embodiments, a dielectric material may be formed between the pedestal 106 and the passive component structure 104. The dielectric material could include material to bond the passive component structure 104 to the pedestal 106 or other suitable material (e.g., to provide electrical insulation between the passive component structure 104 and the pedestal 106 when the pedestal 106 comprises a conductive material).

In some embodiments, the pedestal does not include active circuitry (e.g., the pedestal does not have any transistors). In various embodiments, the pedestal may predominantly, substantially, or completely comprise a dielectric material (such as any of those listed above).

In some embodiments, the pedestal 106 may have substantially the same footprint (e.g., dimensions in a horizontal plane) as the passive component structure 104. In other embodiments, the pedestal 106 may have a larger footprint (e.g., may have a greater width or depth) than the passive component structure 104. In various embodiments, the passive component structure 104 and/or the pedestal 106 may have a generally rectilinear shape.

The passive component structure 104 and the pedestal 106 may be placed within a cavity of the core layer 108. In some embodiments, multiple passive component structure and pedestal pairs may be placed within the same cavity of core layer 108 or in respective cavities within the core layer 108. In some embodiments, multiple passive component structures 104 may be placed on the same pedestal.

The package may also comprise a dielectric material 118 (e.g., a molding material) formed within the cavity of the core layer 108 that encapsulates the passive component structure 104 and pedestal 106.

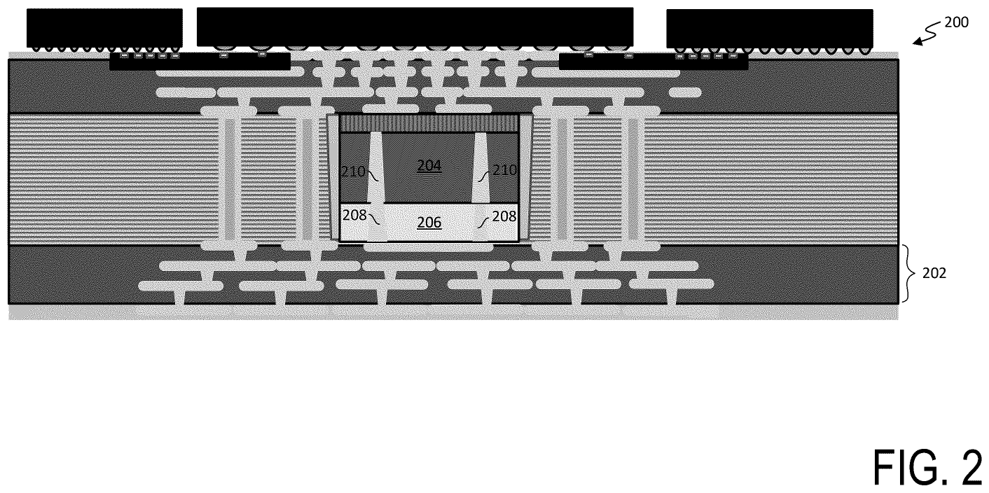

FIG. 2 illustrates a package 200 with an embedded passive component structure 204 and a pedestal 206 with vias, in accordance with any of the embodiments disclosed herein. In this example, the pedestal 206 may comprise vias 208. The vias 208 may couple conductive material within the outer layer 202 to corresponding vias 210 of the passive component structure 204. The vias 210 may then couple to conductive material (e.g., an electrode) of the passive component structure 204.

Vias 208 and/or 210 may comprise through holes (e.g., through-silicon-vias) for power delivery (e.g., a Vss or ground signal) to a passive circuit component within the passive component structure 204 (e.g., to an electrode of a DTC). Such embodiments may simplify the netlist/bump mapping on the top side of the passive component structure 204 and/or decrease the amount of bumps on the top side. In other embodiments, a power supply signal (e.g., Vcc) may be coupled to the passive circuit component using the vias 208 and 210.

In embodiments, where electrical contact is needed between the pedestal 206 and the outer layer 202, the pedestal 206 may be coupled to the package substrate (e.g., the outer layer 202) using bump bonding or hybrid bonding or other suitable technique to couple the vias 208 to conductive material of the package substrate.

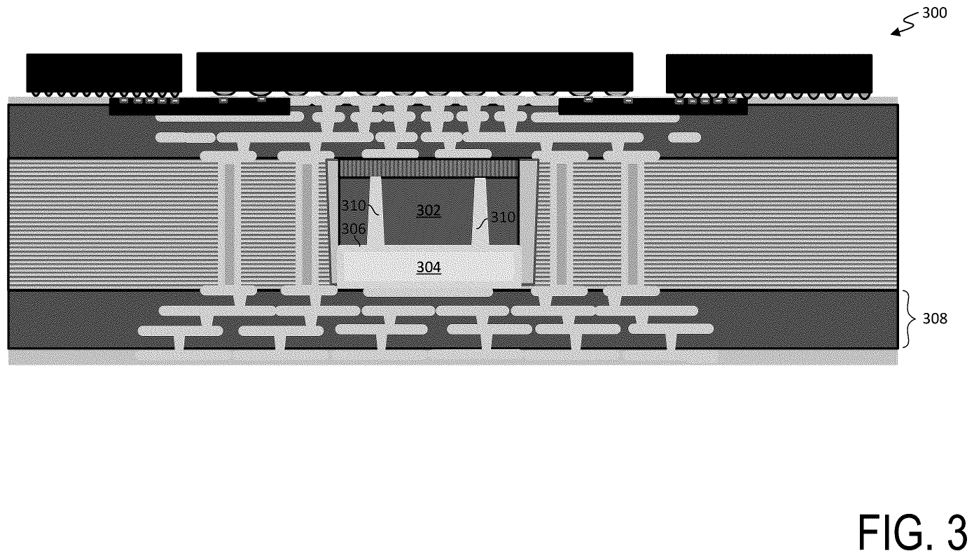

FIG. 3 illustrates a package 300 with an embedded passive component structure 302 and a pedestal 304 with conductive material 306 on its outer edge, in accordance with any of the embodiments disclosed herein. The conductive material 306 may couple conductive material within the outer layer 308 to one or more vias 310 of the passive component structure 302. The vias 310 may then couple to conductive material (e.g., an electrode) of the passive component structure 302.

Conductive material 306 and vias 310 may provide power delivery (e.g., a Vss or ground signal) to a passive circuit component within the passive component structure 302 (e.g., to an electrode of a DTC). Such embodiments may simplify the netlist/bump mapping on the top side of the passive component structure 302. In other embodiments, a power supply signal (e.g., Vcc) may be coupled to the passive circuit component using the conductive material 306 and vias 310.

In some embodiments, the pedestal 304 may be entirely coated on its outer surface with the conductive material 306 or may entirely consist of metal. In other embodiments, only a portion of the outer surface of the pedestal 304 comprises the conductive material 306 (e.g., the outer surface of the pedestal 304 may comprise one or more traces).

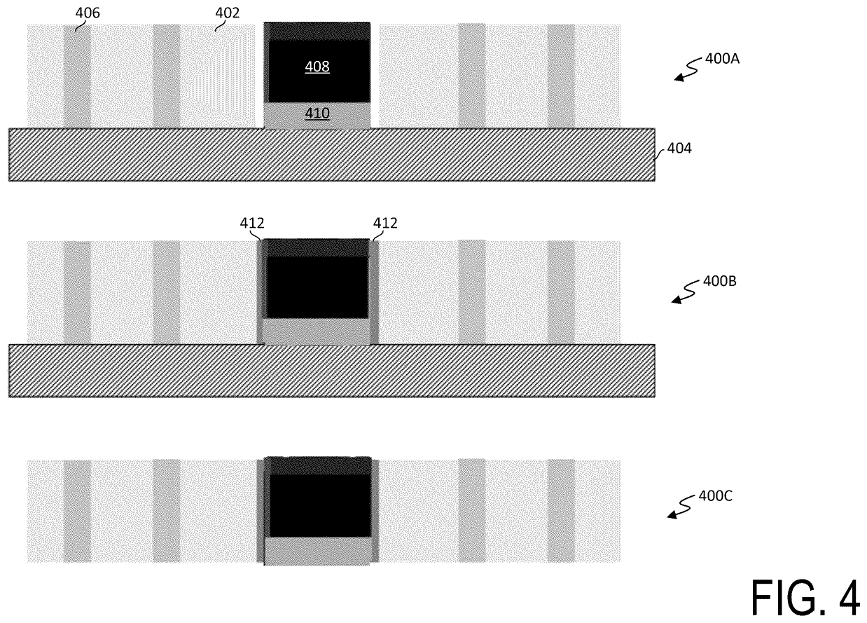

FIG. 4 illustrates example stages 400A-C of a first method of manufacture of a package substrate with an embedded passive component structure and a pedestal, in accordance with any of the embodiments disclosed herein. At stage 400A a passive component structure 408 that is stacked on a pedestal 410 is placed into a cavity of a core layer 402 of a package substrate. The pedestal 410 is placed on a carrier 404. In various embodiments, the pedestal 410 may be attached to the carrier via any suitable manner (e.g., with a bond film).

The core layer 402 may also be placed on the carrier 404 (either before or after the cavity is formed in the core layer 402). The core layer 402 includes various plated through holes 406 extending from the top to the bottom of the core layer.

The carrier may be any suitable structure, such as a glass wafer, a silicon wafer, a metal wafer, a panel, or other suitable structure.

At stage 400B, a dielectric material 412 is formed (e.g., by molding or encapsulation) in the cavity around the passive component structure 408 and pedestal 410. The dielectric material may surround the sides of the passive component structure 408 and pedestal 410. In at least some embodiments, the dielectric material 412 is not formed underneath pedestal 410. Chemical-mechanical polishing (CMP) may then be performed to planarize the top of the structure.

At stage 400C, the carrier 404 is removed and subsequent processing is performed on the package substrate. For example, the outside layers may be formed on the top and bottom of the core layer 402.

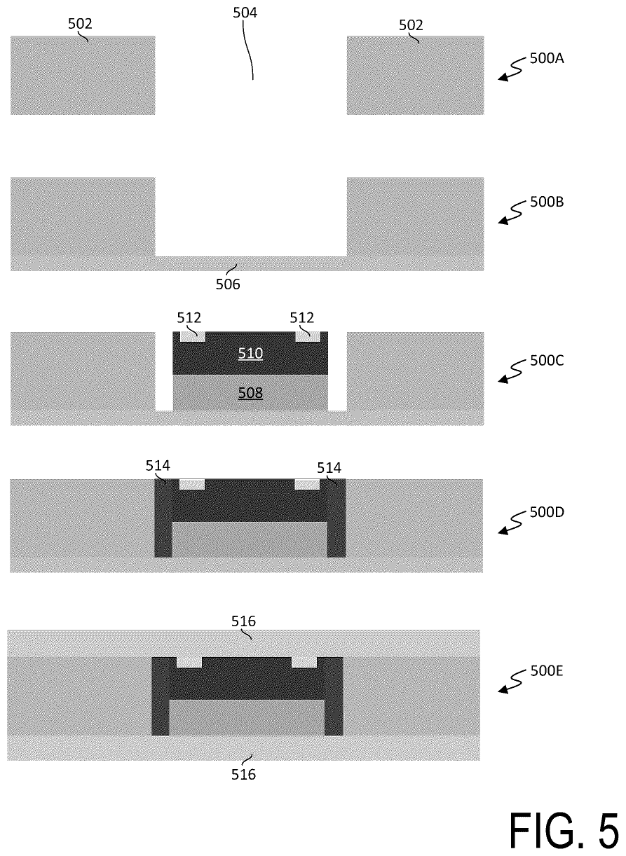

FIG. 5 illustrates example stages 500A-E of a second method of manufacture of a package substrate with an embedded passive component structure and a pedestal, in accordance with any of the embodiments disclosed herein.

The method begins at stage 500A, with a core layer 502 in which a cavity 504 has been formed. The cavity 504 may be formed in any suitable manner, for example, material of the core layer 502 may be removed using a mechanical drill or a laser to form the cavity.

At stage 500B, a temporary carrier 506 is attached to the underside of the core layer 502.

At stage 500C, a pedestal 508 and passive component structure 510 that is attached to the top of the pedestal 508 are placed on the carrier 506 within the cavity of the core layer 502. In various embodiments, the passive component structure 510 may be attached to the pedestal 508 prior to placement of these structures within the cavity 504. In other embodiments, the pedestal 508 may be attached on top of the carrier 506 in the cavity 504 and then the passive component structure 510 may be attached on top of the pedestal 508. The passive component structure 510 may be attached to the pedestal 508 in any suitable manner, such as glue, epoxy, bond film, bump bonding, hybrid bonding, or other suitable manner. The passive component structure may include one or more passive components and one or more electrode pads 512.

At stage 500D, an encapsulation material 514 (e.g., a dielectric material or other suitable material) is formed in the cavity 504 around the pedestal 508 and the passive component structure 510 and planarization may be performed on the top of the structure. In various embodiments, the encapsulation material may comprise, e.g., one or more of a resin, a filler, an epoxy, or other suitable material to fill in the cavity of the core layer 502.

At stage 500E, a substrate build-up process is performed to form metallization and dielectric layers of the outer layers 516 on the top and bottom of the core layer and the embedded passive component structure 510.

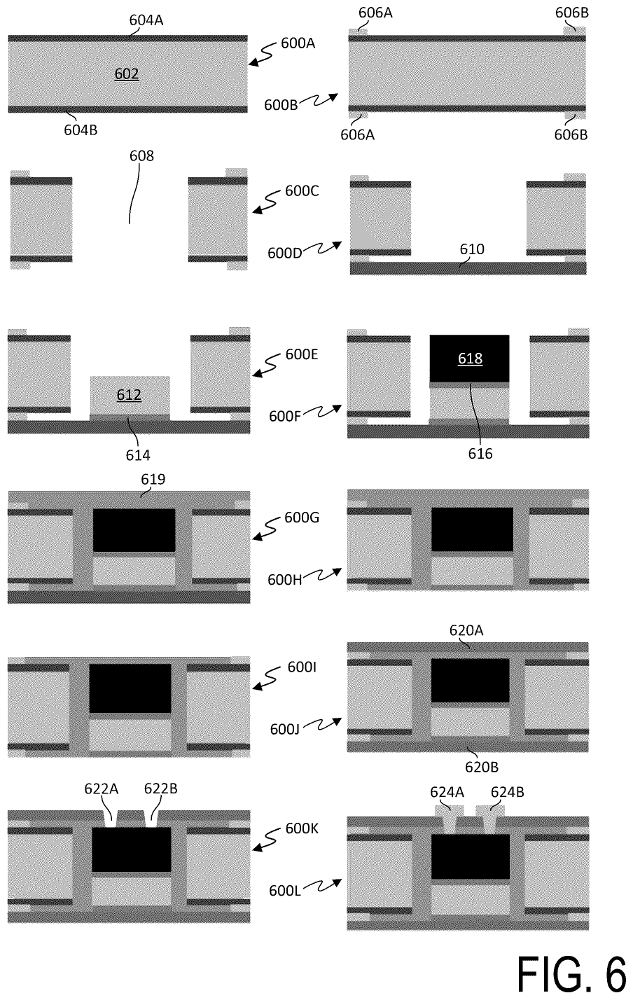

FIG. 6 illustrates example stages 600A-L of a third method of manufacture of a package substrate with an embedded passive component structure and a pedestal, in accordance with any of the embodiments disclosed herein.

At stage 600A, conductive material (e.g., copper) patterning 604A and 604B is formed on a core layer 602. At stage 600B, plate through holes 606A and 606B are formed through the core layer 602.

At stage 600C, a cavity 608 is created within the core layer 602, e.g., by mechanical drilling or other means. At stage 600D, a temporary carrier 610 is attached to the underside of the core layer and/or metallization formed on the core layer.

At stage 600E, a pedestal 612 is attached to the temporary carrier 610 (e.g., with an adhesion film 614 or other means) within the cavity 608. At stage 600F, a passive component structure 618 is mounted on top of the pedestal 612 (e.g., using an additional adhesion film 616 or other means).

At stage 600G, a dielectric layer 619 may be laminated, coated, or filled by any suitable encapsulation process (e.g., vacuum lamination, liquid coating, molding process, etc.). In some instances, portions of the dielectric layer are formed over the plated through holes 606.

At stage 600H, the temporary carrier 610 is removed. At stage 600I, a grinding or other planarization process is performed to remove undesired portions of the dielectric layer 619 and to smooth out the top of the structure. At stage 600J, additional dielectric layers 620A and 620B are formed on the top and bottom of the structure (e.g., by lamination).

At stage 600K, vias may be formed (e.g., laser drilled) through the dielectric layers 620A and 619 (and through the passive component structure 618 if necessary). At stage 600L, a conductive material is formed in the vias to form pads 624A and 624B that connect to one or more passive components (e.g., a DTC) of the passive component structure 618.

In this instance, the pads 624A, 624B are one layer above the plated through holes (whereas in other embodiments the electrodes may be on the same layer as the plated through holes).

Although various stages are shown in the various methods of manufacturing, other embodiments contemplate additional stages, fewer stages, or different orders for the stages.

Where various characteristics are described or illustrated in a particular FIG. for a particular component (e.g., a pedestal, a passive component structure, a core layer, an outer layer, etc.), the various embodiments described herein contemplate that any suitable combination of such characteristics may also apply to the same component as described or illustrated in another FIG.

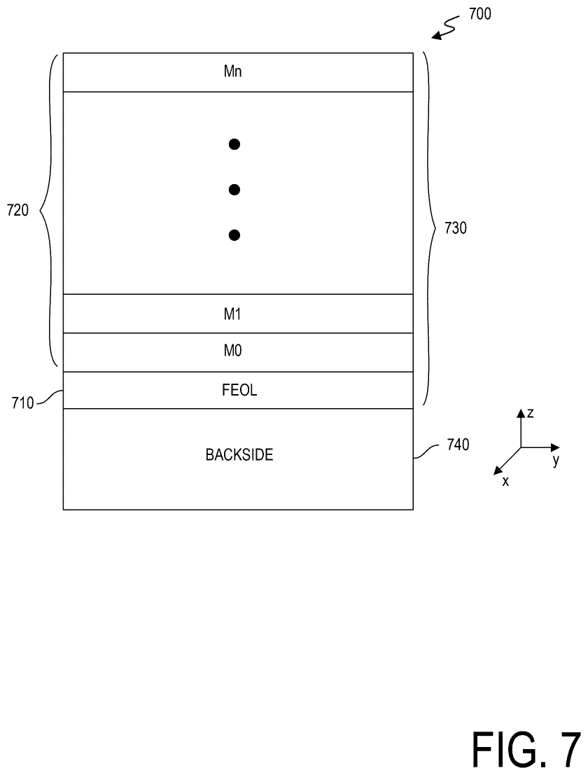

FIG. 7 provides a schematic illustration of a cross-sectional view of an example integrated circuit device (e.g., a chip or die) 700. The IC device 700 may include transistors as well as other circuit elements (e.g., resistors, diodes, capacitors, inductors, etc.). The IC device 700 may represent a die that may be attached to a package substrate in various embodiments.

As shown in FIG. 7, the IC device 700 may include a front side 730 comprising a front-end-of-line (FEOL) 710 that includes various logic layers, circuits, and devices to drive and control a logic IC. These circuits and devices may be configured for any number of functions, such as logic or compute transistors, input/output (I/O) transistors, access or switching transistors, and/or radio frequency (RF) transistors, to name a few examples. According to some embodiments, in addition to these devices and circuits, FEOL 710 may include, for example, one or more other layers or structures associated with the semiconductor devices and circuits. For example, the FEOL can also include a substrate and one or more dielectric layers that surround active and/or conductive portions of the devices and circuits. The FEOL may also include one or more conductive contacts that provide electrical contact to transistor elements such as gate structures, drain regions, or source regions. The FEOL may also include local interconnect (e.g., vias or lines) that connect contacts to interconnect features within a back-end-of-line (BEOL) 720.

The front side 730 of the IC device 700 also includes a BEOL 720 including various metal interconnect layers (e.g., metal 0 through metal n, where n is any suitable integer). Various metal layers of the BEOL 720 may be used to interconnect the various inputs and outputs of the FEOL 710.

Generally speaking, each of the metal layers of the BEOL 720, e.g., each of the layers M0-Mn shown in FIG. 7, may include a via portion and a trench/interconnect portion. Typically, the trench portion of a metal layer is above the via portion, but, in other embodiments, a trench portion may be provided below a via portion of any given metal layer of the BEOL 720. The trench portion of a metal layer may be configured for transferring signals and power along metal lines (also sometimes referred to as “trenches”) extending in the x-y plane (e.g., in the x or y directions), while the via portion of a metal layer may be configured for transferring signals and power through metal vias extending in the z-direction, e.g., to any of the adjacent metal layers above or below. Accordingly, vias connect metal structures (e.g., metal lines or vias) from one metal layer to metal structures of an adjacent metal layer. While referred to as “metal” layers, various layers of the BEOL 720, e.g., layers M0-Mn shown in FIG. 7, may include certain patterns of conductive metals, e.g., copper (Cu) or aluminum (Al), or metal alloys, or more generally, patterns of an electrically conductive material (e.g., including carbon based materials), formed in an insulating medium such as an interlayer dielectric (ILD). The insulating medium may include any suitable ILD materials such as silicon oxide, silicon nitride, aluminum oxide, and/or silicon oxynitride. In various embodiments, any one or more of these layers may additionally include active devices (e.g., transistors, diodes) and/or passive devices (e.g., capacitors, resistors, inductors).

The IC device 700 may also include a backside 740. For example, the backside 740 may formed on the opposite side of a wafer from the front side 730. In various embodiments, the backside 740 may include any suitable elements to assist operation of the IC device 700. For example, the backside 740 may include various metal layers to deliver power to logic of the FEOL 710.

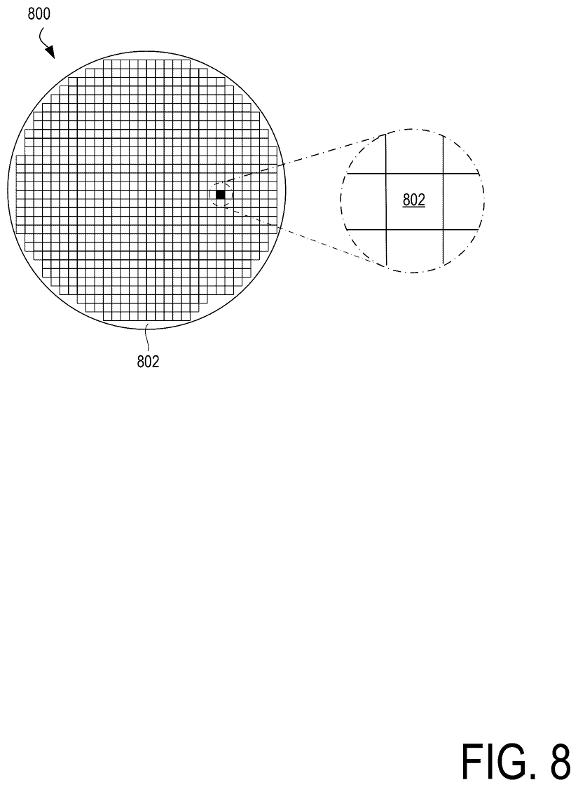

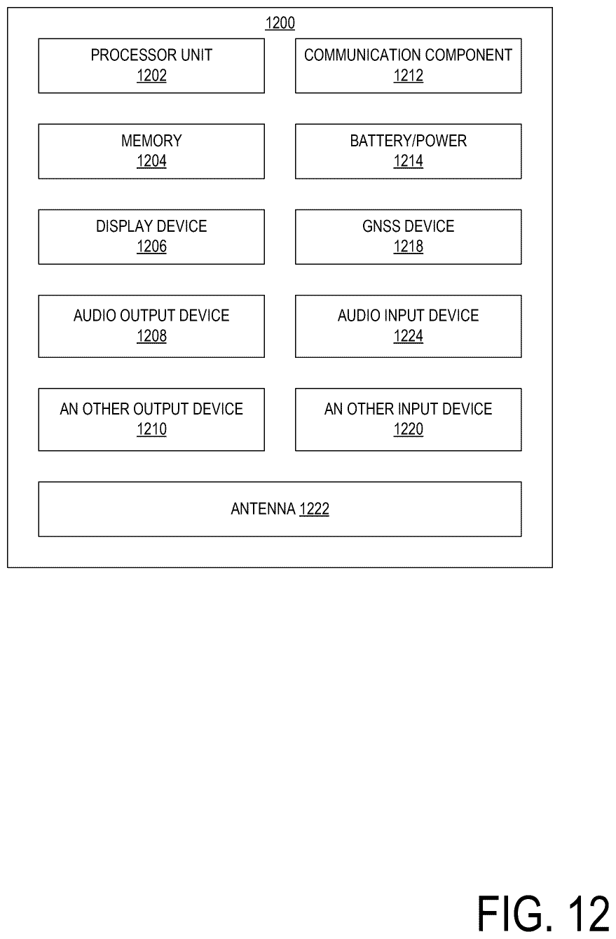

FIG. 8 is a top view of a wafer 800 and dies 802, wherein individual dies may be attached to a package substrate with an embedded passive device structure and pedestal as disclosed herein. The wafer 800 may be composed of semiconductor material and may include one or more dies 802 having integrated circuit structures formed on a surface of the wafer 800. The individual dies 802 may be a repeating unit of an integrated circuit product that includes any suitable integrated circuit. After the fabrication of the semiconductor product is complete, the wafer 800 may undergo a singulation process in which the dies 802 are separated from one another to provide discrete “chips” of the integrated circuit product. The die 802 may include one or more transistors, supporting circuitry to route electrical signals to the transistors, passive components (e.g., signal traces, resistors, capacitors, or inductors), and/or any other integrated circuit components. In some embodiments, the wafer 800 or the die 802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 802. For example, a memory array formed by multiple memory devices may be formed on a same die 802 as a processor unit (e.g., the processor unit 1202 of FIG. 12) or other logic that is configured to store information in the memory devices or execute instructions stored in the memory array. In some embodiments, various ones of the microelectronic assemblies disclosed herein may be manufactured using a die-to-wafer assembly technique in which some dies are attached to a wafer 800 that include other dies, and the wafer 800 is subsequently singulated.

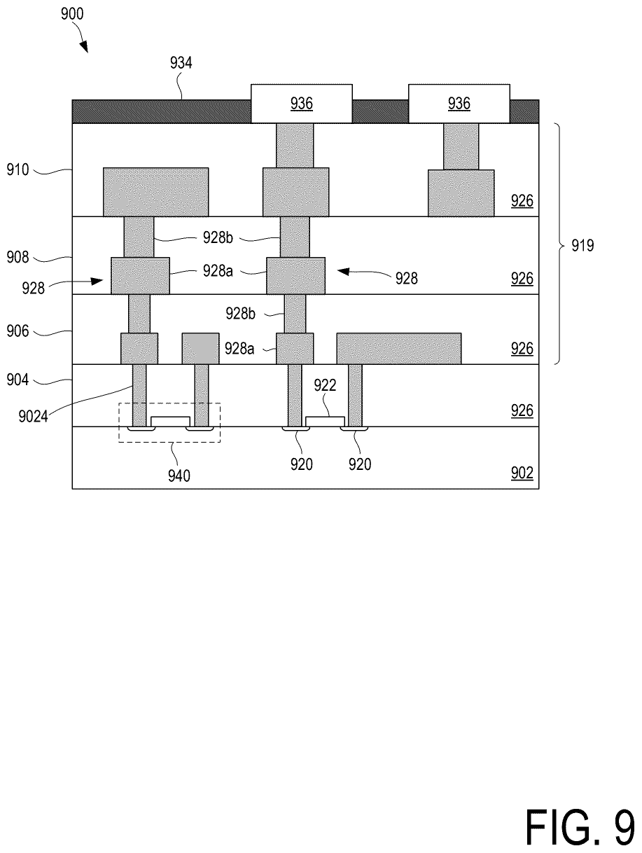

FIG. 9 is a cross-sectional side view of an integrated circuit device 900 that may be attached to a substrate package with an embedded passive device structure and pedestal as disclosed herein. One or more of the integrated circuit devices 900 may be included in one or more dies 802 (FIG. 8). The integrated circuit device 900 may be formed on a die substrate 902 (e.g., the wafer 800 of FIG. 8) and may be included in a die (e.g., the die 802 of FIG. 8). The die substrate 902 may be a semiconductor substrate composed of semiconductor material systems including, for example, n-type or p-type materials systems (or a combination of both). The die substrate 902 may include, for example, a crystalline substrate formed using a bulk silicon or a silicon-on-insulator (SOI) substructure. In some embodiments, the die substrate 902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an integrated circuit device 900 may be used. The die substrate 902 may be part of a singulated die (e.g., the dies 802 of FIG. 8) or a wafer (e.g., the wafer 800 of FIG. 8).

The integrated circuit device 900 may include one or more device layers 904 disposed on the die substrate 902. The device layer 904 may include features of one or more transistors 940 (e.g., metal oxide semiconductor field-effect transistors (MOSFETs)) formed on the die substrate 902. The transistors 940 may include, for example, one or more source and/or drain (S/D) regions 920, a gate 922 to control current flow between the S/D regions 920, and one or more S/D contacts 924 to route electrical signals to/from the S/D regions 920. The transistors 940 may include additional features not depicted for the sake of clarity, such as device isolation regions, gate contacts, and the like. The transistors 940 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

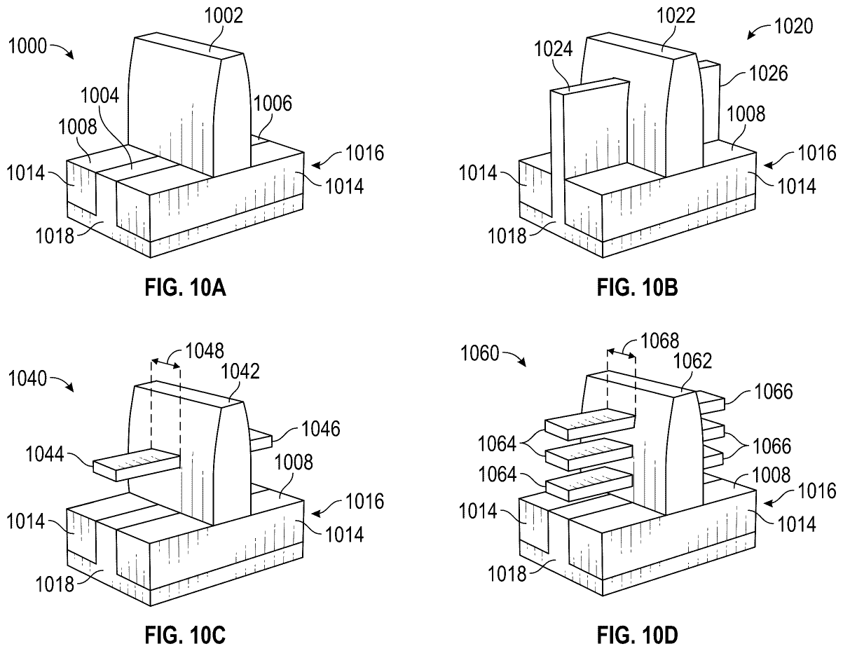

FIGS. 10A-10D are simplified perspective views of example planar, FinFET, gate-all-around, and stacked gate-all-around transistors. The transistors illustrated in FIGS. 10A-10D are formed on a substrate 1016 having a surface 1008. Isolation regions 1014 separate the source and drain regions of the transistors from other transistors and from a bulk region 1018 of the substrate 1016.

FIG. 10A is a perspective view of an example planar transistor 1000 comprising a gate 1002 that controls current flow between a source region 1004 and a drain region 1006. The transistor 1000 is planar in that the source region 1004 and the drain region 1006 are planar with respect to the substrate surface 1008.

FIG. 10B is a perspective view of an example FinFET transistor 1020 comprising a gate 1022 that controls current flow between a source region 1024 and a drain region 1026. The transistor 1020 is non-planar in that the source region 1024 and the drain region 1026 comprise “fins” that extend upwards from the substrate surface 1028. As the gate 1022 encompasses three sides of the semiconductor fin that extends from the source region 1024 to the drain region 1026, the transistor 1020 can be considered a tri-gate transistor. FIG. 10B illustrates one S/D fin extending through the gate 1022, but multiple S/D fins can extend through the gate of a FinFET transistor.

FIG. 10C is a perspective view of a gate-all-around (GAA) transistor 1040 comprising a gate 1042 that controls current flow between a source region 1044 and a drain region 1046. The transistor 1040 is non-planar in that the source region 1044 and the drain region 1046 are elevated from the substrate surface 1028.

FIG. 10D is a perspective view of a GAA transistor 1060 comprising a gate 1062 that controls current flow between multiple elevated source regions 1064 and multiple elevated drain regions 1066. The transistor 1060 is a stacked GAA transistor as the gate controls the flow of current between multiple elevated S/D regions stacked on top of each other. The transistors 1040 and 1060 are considered gate-all-around transistors as the gates encompass all sides of the semiconductor portions that extends from the source regions to the drain regions. The transistors 1040 and 1060 can alternatively be referred to as nanowire, nanosheet, or nanoribbon transistors depending on the width (e.g., widths 1048 and 1068 of transistors 1040 and 1060, respectively) of the semiconductor portions extending through the gate.

Returning to FIG. 9, a transistor 940 may include a gate 922 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 940 is to be a p-type metal oxide semiconductor (PMOS) or an n-type metal oxide semiconductor (NMOS) transistor. In some implementations, the gate electrode may consist of or comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 940 along the source-channel-drain direction, the gate electrode may consist of or comprise a U-shaped structure that includes a bottom portion substantially parallel to the surface of the die substrate 902 and two sidewall portions that are substantially perpendicular to the top surface of the die substrate 902. In other embodiments, at least one of the metal layers that form the gate electrode may simply be a planar layer that is substantially parallel to the top surface of the die substrate 902 and does not include sidewall portions substantially perpendicular to the top surface of the die substrate 902. In other embodiments, the gate electrode may consist of or comprise a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 920 may be formed within the die substrate 902 adjacent to the gate 922 of individual transistors 940. The S/D regions 920 may be formed using an implantation/diffusion process or an etching/deposition process, for example. In the former process, dopants such as boron, aluminum, antimony, phosphorous, or arsenic may be ion-implanted into the die substrate 902 to form the S/D regions 920. An annealing process that activates the dopants and causes them to diffuse farther into the die substrate 902 may follow the ion-implantation process. In the latter process, the die substrate 902 may first be etched to form recesses at the locations of the S/D regions 920. An epitaxial deposition process may then be carried out to fill the recesses with material that is used to fabricate the S/D regions 920. In some implementations, the S/D regions 920 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 920 may be formed using one or more alternate semiconductor materials such as germanium or a group III-V material or alloy. In further embodiments, one or more layers of metal and/or metal alloys may be used to form the S/D regions 920.

Electrical signals, such as power and/or input/output (I/O) signals, may be routed to and/or from the devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with the interconnect structures 928 of the interconnect layers 906-910. The one or more interconnect layers 906-910 may form a metallization stack (also referred to as an “ILD stack”) 919 of the integrated circuit device 900.

The interconnect structures 928 (e.g., lines) may be arranged within the interconnect layers 906-910 to route electrical signals according to a wide variety of designs; in particular, the arrangement is not limited to the particular configuration of interconnect structures 928 depicted in FIG. 9. Although a particular number of interconnect layers 906-910 is depicted in FIG. 9, embodiments of the present disclosure include integrated circuit devices having more or fewer interconnect layers than depicted.

In some embodiments, the interconnect structures 928 may include lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and out of the page and/or in a direction across the page. The vias 928b may be arranged to route electrical signals in a direction of a plane that is substantially perpendicular to the surface of the die substrate 902 upon which the device layer 904 is formed. In some embodiments, the vias 928b may electrically couple lines 928a of different interconnect layers 906-910 together.

The interconnect layers 906-910 may include a dielectric material 926 disposed between the interconnect structures 928, as shown in FIG. 9. In some embodiments, dielectric material 926 disposed between the interconnect structures 928 in different ones of the interconnect layers 906-910 may have different compositions; in other embodiments, the composition of the dielectric material 926 between different interconnect layers 906-910 may be the same. The device layer 904 may include a dielectric material 926 disposed between the transistors 940 and a bottom layer of the metallization stack as well. The dielectric material 926 included in the device layer 904 may have a different composition than the dielectric material 926 included in the interconnect layers 906-910; in other embodiments, the composition of the dielectric material 926 in the device layer 904 may be the same as a dielectric material 926 included in any one of the interconnect layers 906-910.

A first interconnect layer 906 (referred to as Metal 1 or “M1”) may be formed directly on the device layer 904. In some embodiments, the first interconnect layer 906 may include lines 928a and/or vias 928b, as shown. The lines 928a of the first interconnect layer 906 may be coupled with contacts (e.g., the S/D contacts 924) of the device layer 904. The vias 928b of the first interconnect layer 906 may be coupled with the lines 928a of a second interconnect layer 908.

The second interconnect layer 908 (referred to as Metal 2 or “M2”) may be formed directly on the first interconnect layer 906. In some embodiments, the second interconnect layer 908 may include via 928b to couple the lines 928 of the second interconnect layer 908 with the lines 928a of a third interconnect layer 910. Although the lines 928a and the vias 928b are structurally delineated with a line within individual interconnect layers for the sake of clarity, the lines 928a and the vias 928b may be structurally and/or materially contiguous (e.g., simultaneously filled during a dual-damascene process) in some embodiments.

The third interconnect layer 910 (referred to as Metal 3 or “M3”) (and additional interconnect layers, as desired) may be formed in succession on the second interconnect layer 908 according to similar techniques and configurations described in connection with the second interconnect layer 908 or the first interconnect layer 906. In some embodiments, the interconnect layers that are “higher up” in the metallization stack 919 in the integrated circuit device 900 (i.e., farther away from the device layer 904) may be thicker that the interconnect layers that are lower in the metallization stack 919, with lines 928a and vias 928b in the higher interconnect layers being thicker than those in the lower interconnect layers.

The integrated circuit device 900 may include a solder resist material 934 (e.g., polyimide or similar material) and one or more conductive contacts 936 formed on the interconnect layers 906-910. In FIG. 9, the conductive contacts 936 are illustrated as taking the form of bond pads. The conductive contacts 936 may be electrically coupled with the interconnect structures 928 and configured to route the electrical signals of the transistor(s) 940 to external devices. For example, solder bonds may be formed on the one or more conductive contacts 936 to mechanically and/or electrically couple an integrated circuit die including the integrated circuit device 900 with another component (e.g., a printed circuit board). The integrated circuit device 900 may include additional or alternate structures to route the electrical signals from the interconnect layers 906-910; for example, the conductive contacts 936 may include other analogous features (e.g., posts) that route the electrical signals to external components.

In some embodiments in which the integrated circuit device 900 is a double-sided die, the integrated circuit device 900 may include another metallization stack (not shown) on the opposite side of the device layer(s) 904. This metallization stack may include multiple interconnect layers as discussed above with reference to the interconnect layers 906-910, to provide conductive pathways (e.g., including conductive lines and vias) between the device layer(s) 904 and additional conductive contacts (not shown) on the opposite side of the integrated circuit device 900 from the conductive contacts 936.

In other embodiments in which the integrated circuit device 900 is a double-sided die, the integrated circuit device 900 may include one or more through silicon vias (TSVs) through the die substrate 902; these TSVs may make contact with the device layer(s) 904, and may provide conductive pathways between the device layer(s) 904 and additional conductive contacts (not shown) on the opposite side of the integrated circuit device 900 from the conductive contacts 936. In some embodiments, TSVs extending through the substrate can be used for routing power and ground signals from conductive contacts on the opposite side of the integrated circuit device 900 from the conductive contacts 936 to the transistors 940 and any other components integrated into the integrated circuit device (e.g., die) 900, and the metallization stack 919 can be used to route I/O signals from the conductive contacts 936 to transistors 940 and any other components integrated into the integrated circuit device (e.g., die) 900.

Multiple integrated circuit devices 900 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

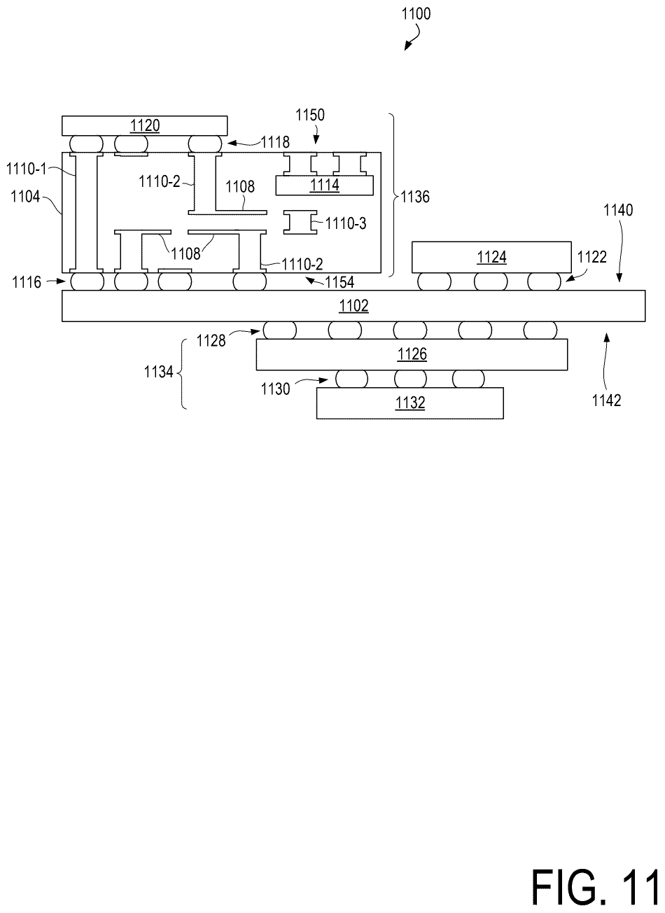

FIG. 11 is a cross-sectional side view of an integrated circuit device assembly 1100 that may include a substrate package with an embedded passive device structure and pedestal as disclosed herein. In some embodiments, the integrated circuit device assembly 1100 may be a microelectronic assembly. The integrated circuit device assembly 1100 includes a number of components disposed on a circuit board 1102 (which may be a motherboard, system board, mainboard, etc.). The integrated circuit device assembly 1100 includes components disposed on a first face 1140 of the circuit board 1102 and an opposing second face 1142 of the circuit board 1102; generally, components may be disposed on one or both faces 1140 and 1142.

In some embodiments, the circuit board 1102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1102. In other embodiments, the circuit board 1102 may be a non-PCB substrate. The integrated circuit device assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1136 may include an integrated circuit component 1120 coupled to an interposer 1104 by coupling components 1118. The coupling components 1118 may take any suitable form for the application, such as the forms discussed above with reference to the coupling components 1116. Although a single integrated circuit component 1120 is shown in FIG. 11, multiple integrated circuit components may be coupled to the interposer 1104; indeed, additional interposers may be coupled to the interposer 1104. The interposer 1104 may provide an intervening substrate used to bridge the circuit board 1102 and the integrated circuit component 1120.

The integrated circuit component 1120 may be a packaged or unpackaged integrated circuit product that includes one or more integrated circuit dies (e.g., the die 802 of FIG. 8, the integrated circuit device 900 of FIG. 9) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1120, a single monolithic integrated circuit die comprises solder bumps attached to contacts on the die. The solder bumps allow the die to be directly attached to the interposer 1104. The integrated circuit component 1120 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1120 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1120 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1104 may spread connections to a wider pitch or reroute a connection to a different connection. For example, the interposer 1104 may couple the integrated circuit component 1120 to a set of ball grid array (BGA) conductive contacts of the coupling components 1116 for coupling to the circuit board 1102. In the embodiment illustrated in FIG. 11, the integrated circuit component 1120 and the circuit board 1102 are attached to opposing sides of the interposer 1104; in other embodiments, the integrated circuit component 1120 and the circuit board 1102 may be attached to a same side of the interposer 1104. In some embodiments, three or more components may be interconnected by way of the interposer 1104.

In some embodiments, the interposer 1104 may be formed as a PCB, including multiple metal layers separated from one another by layers of dielectric material and interconnected by electrically conductive vias. In some embodiments, the interposer 1104 may be formed of an epoxy resin, a fiberglass-reinforced epoxy resin, an epoxy resin with inorganic fillers, a ceramic material, or a polymer material such as polyimide. In some embodiments, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through hole vias 1110-1 (that extend from a first face 1150 of the interposer 1104 to a second face 1154 of the interposer 1104), blind vias 1110-2 (that extend from the first or second faces 1150 or 1154 of the interposer 1104 to an internal metal layer), and buried vias 1110-3 (that connect internal metal layers).

In some embodiments, the interposer 1104 can comprise a silicon interposer. Through silicon vias (TSV) extending through the silicon interposer can connect connections on a first face of a silicon interposer to an opposing second face of the silicon interposer. In some embodiments, an interposer 1104 comprising a silicon interposer can further comprise one or more routing layers to route connections on a first face of the interposer 1104 to an opposing second face of the interposer 1104.

The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art.

The integrated circuit device assembly 1100 may include an integrated circuit component 1124 coupled to the first face 1140 of the circuit board 1102 by coupling components 1122. The coupling components 1122 may take the form of any of the embodiments discussed above with reference to the coupling components 1116, and the integrated circuit component 1124 may take the form of any of the embodiments discussed above with reference to the integrated circuit component 1120.

The integrated circuit device assembly 1100 illustrated in FIG. 11 includes a package-on-package structure 1134 coupled to the second face 1142 of the circuit board 1102 by coupling components 1128. The package-on-package structure 1134 may include an integrated circuit component 1126 and an integrated circuit component 1132 coupled together by coupling components 1130 such that the integrated circuit component 1126 is disposed between the circuit board 1102 and the integrated circuit component 1132. The coupling components 1128 and 1130 may take the form of any of the embodiments of the coupling components 1116 discussed above, and the integrated circuit components 1126 and 1132 may take the form of any of the embodiments of the integrated circuit component 1120 discussed above. The package-on-package structure 1134 may be configured in accordance with any of the package-on-package structures known in the art.

FIG. 12 is a block diagram of an example electrical device 1200 that may include a substrate package with an embedded passive device structure and pedestal as disclosed herein. For example, any suitable components of the electrical device 1200 may include one or more of the integrated circuit device assemblies 1100, integrated circuit components 1120, integrated circuit devices 900, integrated circuit dies 802, or other components disclosed herein. A number of components are illustrated in FIG. 12 as included in the electrical device 1200, but any one or more of these components may be omitted or duplicated, as suitable for the application. In some embodiments, some or all of the components included in the electrical device 1200 may be attached to one or more motherboards mainboards, or system boards. In some embodiments, one or more of these components are fabricated onto a single system-on-a-chip (SoC) die.

Additionally, in various embodiments, the electrical device 1200 may not include one or more of the components illustrated in FIG. 12, but the electrical device 1200 may include interface circuitry for coupling to the one or more components. For example, the electrical device 1200 may not include a display device 1206, but may include display device interface circuitry (e.g., a connector and driver circuitry) to which a display device 1206 may be coupled. In another set of examples, the electrical device 1200 may not include an audio input device 1224 or an audio output device 1208, but may include audio input or output device interface circuitry (e.g., connectors and supporting circuitry) to which an audio input device 1224 or audio output device 1208 may be coupled.

The electrical device 1200 may include one or more processor units 1202 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1200 may include a memory 1204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1204 may include memory that is located on the same integrated circuit die as the processor unit 1202. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1200 can comprise one or more processor units 1202 that are heterogeneous or asymmetric to another processor unit 1202 in the electrical device 1200. There can be a variety of differences between the processing units 1202 in a system in terms of a spectrum of metrics of merit including architectural, microarchitectural, thermal, power consumption characteristics, and the like. These differences can effectively manifest themselves as asymmetry and heterogeneity among the processor units 1202 in the electrical device 1200.

In some embodiments, the electrical device 1200 may include a communication component 1212 (e.g., one or more communication components). For example, the communication component 1212 can manage wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1212 may operate in accordance with other wireless protocols in other embodiments. The electrical device 1200 may include an antenna 1222 to facilitate wireless communications and/or to receive other wireless communications (such as amplitude modulation (AM) or frequency modulation (FM) radio transmissions).

In some embodiments, the communication component 1212 may manage wired communications, such as electrical, optical, or any other suitable communication protocols (e.g., IEEE 802.3 Ethernet standards). As noted above, the communication component 1212 may include multiple communication components. For instance, a first communication component 1212 may be dedicated to shorter-range wireless communications such as Wi-Fi or Bluetooth, and a second communication component 1212 may be dedicated to longer-range wireless communications such as global positioning system (GPS), EDGE, GPRS, CDMA, WiMAX, LTE, EV-DO, or others. In some embodiments, a first communication component 1212 may be dedicated to wireless communications, and a second communication component 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display device 1206 (or corresponding interface circuitry, as discussed above). The display device 1206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any embedded or wired or wirelessly connected external device that generates an audible indicator, such speakers, headsets, or earbuds.

The electrical device 1200 may include an audio input device 1224 (or corresponding interface circuitry, as discussed above). The audio input device 1224 may include any embedded or wired or wirelessly connected device that generates a signal representative of a sound, such as microphones, microphone arrays, or digital instruments (e.g., instruments having a musical instrument digital interface (MIDI) output). The electrical device 1200 may include a Global Navigation Satellite System (GNSS) device 1218 (or corresponding interface circuitry, as discussed above), such as a Global Positioning System (GPS) device. The GNSS device 1218 may be in communication with a satellite-based system and may determine a geolocation of the electrical device 1200 based on information received from one or more GNSS satellites, as known in the art.

The electrical device 1200 may include an other output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include an other input device 1220 (or corresponding interface circuitry, as discussed above). Examples of the other input device 1220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1200 may be any other electronic device that processes data. In some embodiments, the electrical device 1200 may comprise multiple discrete physical components. Given the range of devices that the electrical device 1200 can be manifested as in various embodiments, in some embodiments, the electrical device 1200 can be referred to as a computing device or a computing system.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

It will also be understood that, although the terms “first,” “second,” and so forth may be used herein to describe various elements, these elements should not be limited by these terms. These terms are only used to distinguish one element from another, and are not intended to imply that the objects so described must be in a given sequence, either temporally, spatially, in ranking or in any other manner. For example, a first contact could be termed a second contact, and, similarly, a second contact could be termed a first contact, without departing from the scope of the present example embodiments. The first contact and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. For example, the phrase “A and/or B” means (A), (B), or (A and B), while the phrase “A, B, and/or C” means (A), (B), (C), (A and B), (A and C), (B and C), or (A, B, and C).

As used throughout this description, and in the claims, a list of items joined by the term “at least one of” or “one or more of” can mean any combination of the listed terms.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Furthermore, the terms “comprising,” “including,” “having,” and the like, as used with respect to embodiments of the present disclosure, are synonymous.

The description may use the phrases “in an embodiment,” “according to some embodiments,” “in accordance with embodiments,” or “in embodiments,” which may each refer to one or more of the same or different embodiments.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 10⁷ Siemens per meter (S/m) at 20 degrees Celsius. Examples of such materials include Cu, Ag, Al, Au, W, Zn and Ni.

The term “signal” may refer to at least one current signal, voltage signal, magnetic signal, or data/clock signal.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices.

The description may use perspective-based descriptions such as top/bottom, in/out, over/under, and the like. Such descriptions are merely used to facilitate the discussion and are not intended to restrict the application of embodiments described herein to any particular orientation.

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer means that at least a part of the first material or layer is in direct physical contact with at least a part of that second material/layer. Similar distinctions are to be made in the context of component assemblies.

As used herein, “A is proximate to B” may mean that A is adjacent to B or A is otherwise near to B.

Unless otherwise specified in the specific context of use, the term “predominantly” means more than 50%, or more than half. For example, a composition that is predominantly a first constituent means more than half of the composition (e.g., by volume) is the first constituent (e.g., >50 at. %). The term “primarily” means the most, or greatest, part. For example, a composition that is primarily a first constituent means the composition has more of the first constituent (e.g., by volume) than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

The terms “substantially,” “close,” “approximately,” “near,” and “about,” generally refer to being within +/−10% of a target value (unless specifically specified).

Unless otherwise specified in the explicit context of their use, the terms “substantially equal,” “about equal” or “approximately equal” mean that there is no more than incidental variation between two things so described. In the art, such variation is typically no more than +/−10% of a predetermined target value.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

Although the figures may illustrate embodiments where structures are substantially aligned to Cartesian axes (e.g., device structures having substantially vertical side walls), positive and negative (re-entrant) sloped feature sidewalls often occur in practice. For example, manufacturing non-idealities may cause one or more structural features to have sloped sidewalls. Thus, attributes illustrated are idealized merely for the sake of clearly describing salient features. It is to be understood that schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes an apparatus comprising a package substrate comprising a core layer; a pedestal embedded in the core layer; and a structure comprising a passive circuit component, wherein the structure is above the pedestal and is embedded in the core layer.

Example 2 includes the subject matter of Example 1, and wherein a combined thickness of the pedestal and structure is substantially equal to a thickness of the core layer.

Example 3 includes the subject matter of any of Examples 1 and 2, and wherein the structure comprises a deep trench capacitor.

Example 4 includes the subject matter of any of Examples 1-3, and wherein the pedestal comprises at least one of silicon, glass, resin, or a metal.

Example 5 includes the subject matter of any of Examples 1-4, and wherein the pedestal comprises a via coupled to the structure.

Example 6 includes the subject matter of any of Examples 1-5, and wherein the via is to carry a ground signal to the structure.

Example 7 includes the subject matter of any of Examples 1-6, and wherein the pedestal comprises a conductive material on an outer edge of the pedestal, wherein the conductive material is coupled to the structure.

Example 8 includes the subject matter of any of Examples 1-7, and wherein the pedestal has a footprint that is substantially the same as a footprint of the structure.

Example 9 includes the subject matter of any of Examples 1-8, and wherein the pedestal has a footprint that is larger than a footprint of the structure.

Example 10 includes the subject matter of any of Examples 1-9, and wherein sides of the pedestal and the structure are in contact with a dielectric material, wherein the dielectric material is in contact with the core layer.

Example 11 includes the subject matter of any of Examples 1-10, and wherein the package substrate further comprises a second pedestal embedded in the core layer; and a second structure comprising a passive circuit component, wherein the second structure is on the pedestal and is embedded in the core layer.

Example 12 includes the subject matter of any of Examples 1-11, and wherein the pedestal, structure, second pedestal, and second structure are within a cavity of the core layer.

Example 13 includes the subject matter of any of Examples 1-12, and further including an integrated circuit device coupled to the package substrate.

Example 14 includes the subject matter of any of Examples 1-13, and further including a printed circuit board coupled to the package substrate.

Example 15 includes an apparatus comprising a core layer; a first outer layer above the core layer, the first outer layer comprising at least one interconnect layer and at least one dielectric layer; a second outer layer below the core layer, the second outer layer comprising at least one interconnect layer and at least one dielectric layer; a first structure within a cavity in the core layer; and a second structure comprising a passive circuit component, wherein the second structure is attached to the first structure and within the cavity in the core layer.

Example 16 includes the subject matter of Example 15, and wherein the passive circuit component comprises a deep trench capacitor.

Example 17 includes the subject matter of any of Examples 15 and 16, and wherein a combined thickness of the first structure and second structure is substantially equal to a thickness of the core layer.

Example 18 includes the subject matter of any of Examples 15-17, and wherein the first structure comprises at least one of silicon, glass, resin, or a metal.

Example 19 includes the subject matter of any of Examples 15-18, and wherein the first structure comprises a via coupled to the second structure.

Example 20 includes the subject matter of any of Examples 15-19, and wherein the via is to carry a ground signal to the second structure.

Example 21 includes the subject matter of any of Examples 15-20, and wherein the first structure comprises a conductive material on an outer edge of the first structure, wherein the conductive material is coupled to the second structure.

Example 22 includes the subject matter of any of Examples 15-21, and wherein the second structure has a footprint that is substantially the same as a footprint of the first structure.

Example 23 includes the subject matter of any of Examples 15-22, and wherein the first structure has a footprint that is larger than a footprint of the second structure.

Example 24 includes the subject matter of any of Examples 15-23, and wherein sides of the first structure and the second structure are in contact with a dielectric material, wherein the dielectric material is in contact with the core layer.

Example 25 includes the subject matter of any of Examples 15-24, and wherein the package substrate further comprises a third structure embedded in the core layer; and a fourth structure comprising a passive circuit component, wherein the fourth structure is on the third structure and is embedded in the core layer.

Example 26 includes the subject matter of any of Examples 15-25, and wherein the first, second, third, and fourth structures are within a cavity of the core layer.

Example 27 includes the subject matter of any of Examples 15-26, and further including an integrated circuit device coupled to the first outer layer.

Example 28 includes the subject matter of any of Examples 15-27, and further including a printed circuit board coupled to the second outer layer.

Example 29 includes a system comprising a package substrate comprising a core layer; a pedestal within a cavity in the core layer; and a structure comprising a passive circuit component, wherein the structure is above the pedestal and within the cavity in the core layer.

Example 30 includes the subject matter of Example 29, and further including a processor coupled to the package substrate.

Example 31 includes the subject matter of any of Examples 29 and 30, and further including at least one of a network interface, battery, or memory coupled to the processor.

Example 32 includes the subject matter of any of Examples 29-31, and wherein a combined thickness of the pedestal and the structure is substantially equal to a thickness of the core layer.

Example 33 includes the subject matter of any of Examples 29-32, and wherein the structure comprises a deep trench capacitor.

Example 34 includes the subject matter of any of Examples 29-33, and wherein the pedestal comprises at least one of silicon, glass, resin, or a metal.

Example 35 includes the subject matter of any of Examples 29-34, and wherein the pedestal comprises a via coupled to the structure.

Example 36 includes the subject matter of any of Examples 29-35, and wherein the via is to carry a ground signal to the structure.

Example 37 includes the subject matter of any of Examples 29-36, and wherein the pedestal comprises a conductive material on an outer edge of the pedestal, wherein the conductive material is coupled to the structure.

Example 38 includes the subject matter of any of Examples 29-37, and wherein the pedestal has a footprint that is substantially the same as a footprint of the structure.

Example 39 includes the subject matter of any of Examples 29-38, and wherein the pedestal has a footprint that is larger than a footprint of the structure.

Example 40 includes the subject matter of any of Examples 29-39, and wherein sides of the pedestal and the structure are in contact with a dielectric material, wherein the dielectric material is in contact with the core layer.

Example 41 includes the subject matter of any of Examples 29-40, and wherein the package substrate further comprises a second pedestal embedded in the core layer; and a second structure comprising a passive circuit component, wherein the second structure is on the second pedestal and is embedded in the core layer.

Example 42 includes the subject matter of any of Examples 29-41, and wherein the pedestal, structure, second pedestal, and second structure are within a cavity of the core layer.

Example 43 includes the subject matter of any of Examples 29-42, and further including an integrated circuit device coupled to the package substrate.

Example 44 includes the subject matter of any of Examples 29-43, and further including a printed circuit board coupled to the package substrate.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

1. An apparatus comprising:
a package substrate comprising:
a core layer;
a pedestal embedded in the core layer; and
a structure comprising a passive circuit component, wherein the structure is above the pedestal and is embedded in the core layer.

2. The apparatus of claim 1, wherein a combined thickness of the pedestal and the structure is substantially equal to a thickness of the core layer.

3. The apparatus of claim 1, wherein the structure comprises a deep trench capacitor.

4. The apparatus of claim 1, wherein the pedestal comprises at least one of silicon, glass, resin, or a metal.

5. The apparatus of claim 1, wherein the pedestal comprises a via coupled to the structure.

6. The apparatus of claim 5, wherein the via is to carry a ground signal to the structure.

7. The apparatus of claim 1, wherein the pedestal comprises a conductive material on an outer edge of the pedestal, wherein the conductive material is coupled to the structure.

8. The apparatus of claim 1, wherein the pedestal has a footprint that is substantially the same as a footprint of the structure.

9. The apparatus of claim 1, wherein the pedestal has a footprint that is larger than a footprint of the structure.

10. The apparatus of claim 1, wherein sides of the pedestal and the structure are in contact with a dielectric material, wherein the dielectric material is in contact with the core layer.

11. The apparatus of claim 1, the package substrate comprising:
a second pedestal embedded in the core layer; and
a second structure comprising a passive circuit component, wherein the second structure is on the second pedestal and is embedded in the core layer.

12. The apparatus of claim 11, wherein the pedestal, structure, second pedestal, and second structure are within a cavity of the core layer.

13. The apparatus of claim 1, further comprising an integrated circuit device coupled to the package substrate.

14. The apparatus of claim 13, further comprising a printed circuit board coupled to the package substrate.

15. An apparatus comprising:
a core layer;
a first outer layer above the core layer, the first outer layer comprising at least one interconnect layer and at least one dielectric layer;
a second outer layer below the core layer, the second outer layer comprising at least one interconnect layer and at least one dielectric layer;
a first structure within a cavity in the core layer; and
a second structure comprising a passive circuit component, wherein the second structure is attached to the first structure and within the cavity in the core layer.

16. The apparatus of claim 15, wherein the passive circuit component comprises a deep trench capacitor.

17. The apparatus of claim 15, wherein a combined thickness of the first structure and second structure is substantially equal to a thickness of the core layer.

18. A system comprising:
a package substrate comprising:
a core layer;
a pedestal within a cavity in the core layer; and
a structure comprising a passive circuit component, wherein the structure is above the pedestal and within the cavity in the core layer.

19. The system of claim 18, comprising a processor coupled to the package substrate.

20. The system of claim 19, further comprising at least one of a network interface, battery, or memory coupled to the processor.
